(19) United States
(12) Patent Application Publication
(10) Pub. No.: US 2014/0203267 A1
(43) Pub. Date: Jul. 24, 2014

(54) Photovoltaic Device

(71) Applicant: Molecular Vision Limited, London (GB)

(72) Inventors: Jingsong Huang, London (GB); Yim Fun Loo, London (GB)

(73) Assignee: Molecular Vision Limited, London (GB)

(21) Appl. No.: 14/224,816

(22) Filed: Mar. 25, 2014

Related U.S. Application Data
(62) Division of application No. 12/678,177, filed on Jun. 29, 2010.

(30) Foreign Application Priority Data
Sep. 14, 2007 (GB) 0718010.2

(51) Int. Cl. H01L 51/42; H01L 51/00

(52) U.S. Cl. CPC H01L 51/424; H01L 51/0046; H01L 51/0036; H01L 51/0047
USPC 257/40

(57) ABSTRACT

A photovoltaic device comprising a first electrode, a second electrode, an active layer between the two electrodes and an interlayer between the active layer and at least one of the electrodes. The interlayer is a conjugated polymer which is preferably in the amorphous phase. The device shows significantly improved voltage-current characteristics compared to prior art devices and is particularly suitable as a low light level detector.

### RELATED APPLICATIONS

This application is a divisional of U.S. application Ser. No. 12/678,177, which is the U.S. National Stage application of International Application No. PCT/GB2008/003090 filed on Sep. 11, 2008, published in English, which claims the benefit of GB Application No. 0718010.2, filed on Sep. 14, 2007. The entire teachings of the above applications are incorporated herein by reference.

### BACKGROUND

A photovoltaic cell is a device that converts optical energy to electrical energy. Uses of photovoltaic cells include generation of electricity as solar cells or in analytical techniques for light detection. The principal mechanism is photoconductivity wherein absorption of a photon results in the generation of an electron-hole pair. The electron and hole separate to become mobile carriers which may be transported through the semiconductor under an electric field. The electric field may arise from a Schottky contact where a built-in potential exists at a metal-semiconductor interface or from a p-n junction between p-type and n-type semiconductive materials. The transport of these carriers enhances the conductivity of the semiconductor. Such devices are usually made from inorganic semiconductors especially silicon due to its high conversion. However, silicon technology has associated high costs and complex manufacturing process steps resulting in devices which are expensive in relation to the power they produce. The development of organic electronics from the eighties of last century has made the organic photovoltaic cell a promised candidate to challenge the dominant position of silicon technology in this field. A photodiode also will act as a source for electrical noise and generate a noise current. The noise current will limit the usefulness of the photodiode at very low light levels where the magnitude of the noise approached that of the signal photocurrent. Due to the nature of organic materials, the noise current in organic photovoltaic cell is relatively high, especially when used in the photoconductive mode. Device architecture has been found to play a crucial role in the performance of organic photovoltaic cells.

Organic photovoltaic cells normally have two kinds of functional materials in the active layer: electron accepting materials and hole accepting materials. Electron accepting material refers to a material which, owing to a higher electron affinity compared to another material, is capable of accepting electrons. Hole accepting material is a material which due to a smaller ionisation potential compared to another material is capable of accepting holes. Similar to their inorganic counterpart, the absorption of light in organic photoconductive materials results in the creation of bound electron-hole pairs. The different feature in organic devices is that the pairs of electron and holes created by the absorption of a photon are only weakly bound. The dissociation of the bound electron-hole pair is facilitated by the interface between electron donor and acceptor. The holes and electrons travel through their respective acceptor materials to be collected at the electrodes. Unlike their counterpart, organic materials usually have much lower carrier mobility, e.g., electron mobility in Silicon at room temperature is about ˜1400 cm²V⁻¹s⁻¹, whereas poly(3-hexylthiophene) has less than 0.1 cm² V⁻¹s⁻¹ hole mobility, which is still very high for an organic semiconductor. In order to reduce significant recombination losses of the charge carriers, easier paths to opposite electrodes for electrons and holes are very important. Therefore, the ideal device structure should satisfy two essential requirements: large enough interface of two functional materials and easy pathways of two charge carriers to their collecting electrodes.

Referring to FIG. 1 there is shown a known organic photovoltaic cell 100 having an photoactive material comprising poly(3-hexylthiophene): 1-(3-Methoxycarbonylpropyl)-1-phenyl-[6.6]C61 (P3HT:PCBM), in which P3HT acts as an electron donor and PCBM acts as the electron acceptor. FIG. 1 shows that the cell comprises, in series: an aluminium electrode 101, a P3HT:PCBM active layer 103; a PEDOT:PSS layer 105; and an ITO substrate 107. The PEDOT:PSS layer 105 and ITO substrate 107 combine to form the anode. The battery 109 is only figurative to show the polarity of the device. The active layer may vary in thickness from a few tens to a few hundreds nanometres or even up to micrometer-scale.

In similar arrangements, C. W. Tang has disclosed two-layer organic photovoltaic cells in U.S. Pat. No. 4,164,431 and U.S. Pat. No. 4,281,053. These were formed in a layer-by-layer fashion, namely, one hole accepting material layer and one electron accepting material layer sandwiched between two electrodes. K. Petritsch et al. (U.S. Pat. No. 6,340,789) fabricated multilayer devices by laminating two components. One component had a first electrode and a first semiconductive layer, another had a second electrode and a second semiconductive layer. They were laminated together by controlled joining of a first semiconductive material and a second semiconductive material. This kind of heterojunction architecture, formed by two neat materials, offers pathways for easier carrier transport. It, however, has a vital drawback: photo-generated excitons have to diffuse toward the interface to get separated. Here, only excitons being created within the exciton diffusion length can contribute to the photocurrent. Unfortunately, the exciton diffusion length in organic materials is often very short. Therefore, this approach is mainly limited by the typically small exciton diffusion length in organic materials.

Moreover, the fabrication of this heterojunction design is limited. When one organic layer is deposited on top of another organic layer, the second layer must be added in such a way that the previously deposited layer is not affected in a detrimental way. Application of this method in polymer electronics is restricted due to its solution process.

The architecture of a trade-off between dissociation of excitons and safe transport of most of the separated carriers was reported recently (T. Tsuzuki, Solar Energy Materials & Solar Cells, 61(2000)1-8; B. Pradhan et al., Synth. Met. 155 (2005) 555 and Appl. Phys. Lett. 85 (2004) 663). This structure has at least one set of three layers between two electrodes. They are a neat electron acceptor layer, a mixture layer of electron acceptor and donor, and a neat electron donor layer. In the mixture layer, the two materials were either mixed uniformly or mixed so as to provide an approximately linear gradient in relative concentration between the two neat layers. This concept has the possibility of enhanced exciton dissociation due to the proximity of donor and acceptor materials in the molecular scale, and provides a better passage for respective charge carriers to the electrodes through the regions of donor and acceptor materials. The presence of neat electron acceptor and donor layers breaks the one component mix extending through the whole device, therefore, high efficiency and low noise device characteristics are expected. However, this structure is very difficult to achieve with polymers.

In a further known arrangement, J. J. M. Halls et al. developed an efficient photodiode from interpenetrating polymer networks (U.S. Pat. No. 5,670,791). It describes the formation of a photovoltaic device by depositing a blend comprising electron donor and acceptor polymers between two electrodes. The two different semiconductive polymers form respective continuous networks so that there is a continuous path through each of the semiconductive polymers and a charge carrier within one of the first and second semiconductive polymers can travel between the first and second electrodes without having to cross into the other semiconductive polymer. This so-called bulk-heterojunction architecture provides maximum interface for excitons to separate. However, this concept also has drawbacks. Bulk generated charge carriers need to percolate within the bulk blend toward their specific electrodes. That may lead to reduced charge carrier mobility by the intermixing of two compounds which again limits the range of active layer thickness accessible without significant recombination losses. Additionally, the dark current of these kinds of devices could be high because both electron acceptor and donor make their own continuous pathway from one electrode to another, e.g. creating a parallel single material diode.

### SUMMARY

The present invention relates to a photovoltaic device, a method of fabricating a photovoltaic device and a light detector or solar cell.

The invention is as set-out in the claims. According to a first aspect of the invention, there is provided a photovoltaic device comprising a substrate, a first electrode, an active layer, a second electrode and an undoped or substantially undoped interlayer located between and in contact with the active layer and at least one of the electrodes. It is recognised according to the invention that in a two-layered system known from the prior art, it is reasonable to expect the two active components to mix uniformly in all directions in their solid films. Therefore, it is very likely that the two components will make contact directly with the two electrodes respectively, and form their own single diodes. In the photoconductive mode, electrons and holes can choose the easier passages to inject into or extract from the active layer. Here, electrons inject into PCBM rather than P3HT and holes inject into P3HT rather than PCBM. It results in a relatively large shot noise current, leading to current-voltage characteristics unlike the saturation characteristics of an ideal photovoltaic cell. The interlayer thus provides the following advantages: 1) preventing the electron acceptor and/or donor from making their own continuous pathway from one electrode to another thereby preventing them from creating their own parallel single material diodes between the two electrodes; 2) preventing electrons from migrating to the anode and holes migrating to the cathode; 3) to facilitate the collection of electrons at the cathode and holes at the anode; and 4) improves the stability of the device.

Doping is a process in which the physical and chemical characteristics of a material are altered by exposure of the material to an oxidising or reducing agent to remove or add electrons.

An undoped interlayer is therefore one in which no foreign species have been introduced to alter, for example, the conductivity; the only foreign species present are intrinsic impurities. In other words, additional materials have not been intentionally added to alter the physical and chemical characteristics of the bulk material.

The interlayer comprises a conjugated polymeric material. Preferably, the polymer is in the amorphous phase. Preferably, the thickness of the interlayer is less than 30 nm and more preferably the thickness is 10 to 20 nm. The thickness of the interlayer is important for device performance because: 1) the interlayer increases the electrical resistance and a thin film is required so as to minimise this increase thereby minimising the effect on the transport of charge carriers and the variation in the electrical potential distribution across the whole device; 2) the interlayer has an optically filtering effect thereby reducing the amount of light that reaches the detector; and 3) the interlayer must be thin enough so that the dissociated photogenerated excitons can contribute to the photocurrent; the interlayer may have a thickness comparable to the exciton diffusion length of the active material. The thickness of the interlayer must be sufficient to allow for a bonding layer to form between the active layer and interlayer such that the interlayer and active layer do not de-bond. The trade-off between all these factors determines the optimum interlayer thickness.

### BRIEF DESCRIPTION OF THE DRAWINGS

FIG. 1 illustrates the architecture of a prior art device;

FIG. 2 shows the generic architecture according to embodiments of the present invention;

FIG. 3 shows the voltage-current characteristics of the prior art device and a device according to the first embodiment;

FIG. 4 shows the voltage-current characteristics of the prior art device and a device according to the second embodiment;

FIG. 5 shows the voltage-current characteristics of the prior art device and a device according to the third embodiment;

FIG. 6 illustrates the responsivity of the prior art device and devices according to embodiments of the present invention;

FIG. 7 illustrates the influence of annealing treatment on absorption spectra of P3HT on PEDOT:PSS coated spectrosil B; and

FIG. 8 illustrates the influence of annealing treatment on photoluminescent spectra of P3HT on PEDOT:PSS coated spectrosil B (normalized at the signal spectrum at ˜500 nm).

### DETAILED DESCRIPTION

Embodiments of the invention will now be described by way of non-limiting example only.

In overview, there is provided a photovoltaic device comprising a first electrode, a second electrode, an active layer between the two electrodes and an interlayer between the active layer and at least one of the electrodes. The interlayer is a conjugated polymer which is preferably in the amorphous phase. The device shows significantly improved voltage-current characteristics compared to prior art devices and is particularly suitable as a low light level detector.

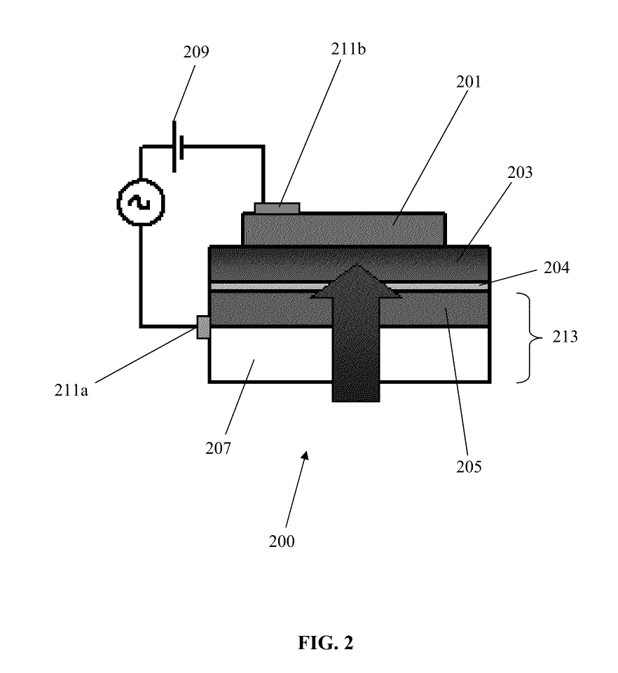

Referring to FIG. 2, there is shown a first embodiment of the present invention which may be made in accordance with Example 1 set-out below. FIG. 2 shows a photovoltaic cell 200 comprising, in series: an aluminium electrode 201; an active P3HT:PCBM layer 203; an interlayer 204 of P3HT; and a second electrode 213 comprising a PEDOT:PSS layer 205 and an ITO substrate 207. The battery 209 is only figurative to show the polarity of the device. The interlayer of P3HT is undoped and is typically less than 30 nm thick, preferably 10 to 20 nm. In alternative embodiments not shown, the interlayer 204 may be between the aluminium electrode 201 and the active layer 205 or between both electrodes 201, 213 and the active layer 203.

In the following illustrative example, all devices are tested in nitrogen at room temperature. The current-voltage characteristics are measured using a Keithley 6517A Electrometer/High Resistance Meter. CM110⅛m Monochromator as the light source for photocurrent measurements.

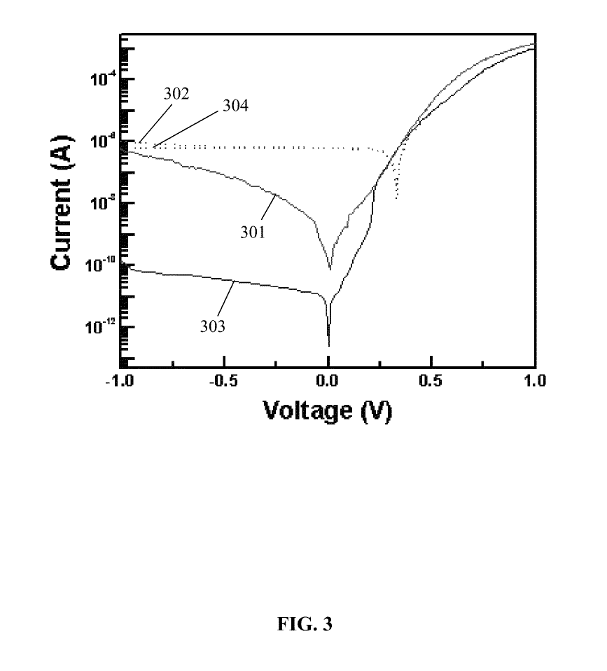

Referring to FIG. 3, there is shown the voltage-current characteristics of the device without an interlayer under dark (plot 301) and light conditions (plot 302). In light conditions (plot 302), the photocurrent is taken under illuminating light of 600 nm with power intensity of 62 μW/cm². The dark current, under the negative bias, increases continuously over 3 orders of magnitude, e.g. −5×10⁻¹⁰ A to 5×10⁻⁷ A from −0.03 V to −0.97 V.

In contrast, plots 303 and 304 in FIG. 3 shows the performance achieved with the photovoltaic cell according to the first embodiment. Here, the dark current (plot 303) is much reduced and more stable over the range −0.03V to −0.97V. The characteristics of the device according to the first embodiment are very similar feature to an ideal photovoltaic cell: a level off current at photoconductive mode. In the same voltage range of (−0.03 V˜0.97V), the current only has small increase but remain in the order of 10⁻¹¹ A. Another pronounced feature is that the device according to the first embodiment has much lower dark current (plot 303) in photovoltaic mode. It is only sub Pico-Ampere, nearly two decades lower than those of the prior art device. As discussed in more detail below, it indicates that device according to the first embodiment has much higher shunt resistance, which has been confirmed by measurement. The light current (plot 304) is substantially similar to that of the prior art device (plot 302).

In a second embodiment, which may be made in accordance with Example 2 set-out below, the interlayer 204 is, instead, poly[2,7-(9,9-di-n-octylfluorene)-alt-(1,4-phenylene-((4-secbutylphenyl)imino)-1,4-phenylene)] (commonly known as TFB) and in a third embodiment which may also be made by Example 2, the interlayer 204 is poly[9,9-diocytlfluorene-co-(bis-N,N′-(3-ethoxyphenyl)-bis-N,N′-phenylbenzidine)] (commonly known as BFE).

As will be understood by the skilled reader, a photovoltaic device may also be characterised by an equivalent circuit which includes shunt resistance and series resistance. As understood in the field, the shunt resistance of the equivalent circuit gives a good indication of the dark current of the device: a high shunt resistance suggests a low dark current.

The shunt resistance is below 70MΩ for the prior art device, while the device according to the first embodiment has a shunt resistance in the range of Giga-ohms. This is more than two orders higher than those found in the prior art device. The dark current floor is comparable to CMOS devices and better than silicon PIN structure photovoltaic cells. Therefore, embodiments of the present invention are suitable for ultra low light level applications.

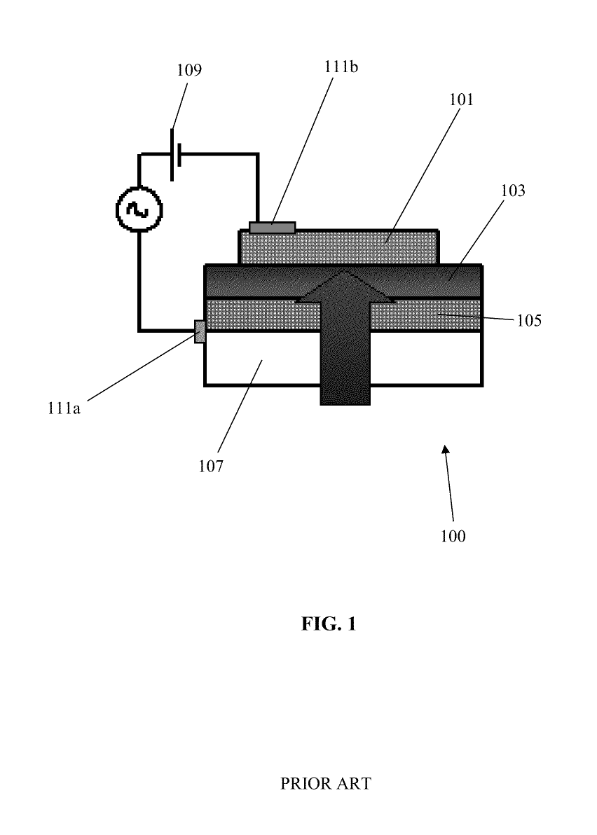

Although the shunt resistance is remarkably increased due to presence of the interlayer, the series resistance is not significantly changed (as shown in the table below). The Series resistance of all devices is comparable to those of Silicon PiN structure photovoltaic cells. Under the illumination conditions (600 nm, 62 μW/cm²), P3HT interlayer devices have slightly higher short circuit current and larger open circuit voltage compared to the control devices.

| | Prior art | 1^{st} | 2^{nd} | 3^{rd} |
|---|---|---|---|---|
| | (FIG. 1) | embodiment | embodiment | embodiment |
| Series R | 270.20 ± 11.43 | 913.18 ± 85.48 | 235.98 ± 4.82 | 4238.80 ± 858.28 |
| (Ω) | | | | |
| Shunt R | 14.59 ± 8.87 | 7944.23 ± 1422.61 | 61.54 ± 15.02 | 133.32 ± 81.9 |
| (MΩ) | | | | |

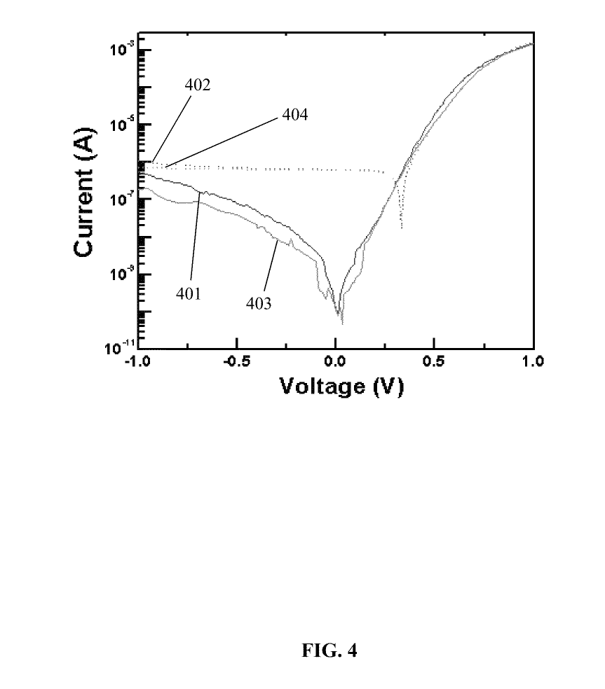

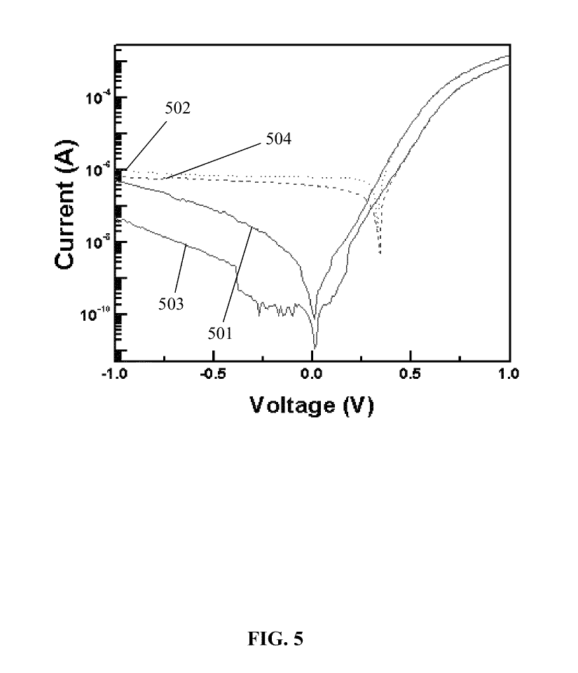

FIGS. 4 and 5 illustrate the voltage-current characteristics of the devices according to the second and third embodiments respectively.

FIG. 4 shows the voltage-current characteristics obtained using the device in accordance with the second embodiment. These results were obtained under the same conditions described with respect to FIG. 3. Again, the characteristics of the prior art device are shown for comparative purposes. Referring to FIG. 4, plots 401 and 402 show the dark and light currents respectively of the device without the interlayer. Plots 403 and 404 show the dark and light currents respectively of a device according to the second embodiment.

Likewise, FIG. 5 shows the voltage-current characteristics of the device according to the third embodiment. Referring to FIG. 5, plots 501 and 502 show the dark and light currents respectively of the device without the interlayer. Plots 503 and 504 show the dark and light currents respectively of a device according to the third embodiment. Although the second and third embodiments show an improvement over the prior art device, the dark current is not as significantly reduced as with the first embodiment (P3HT).

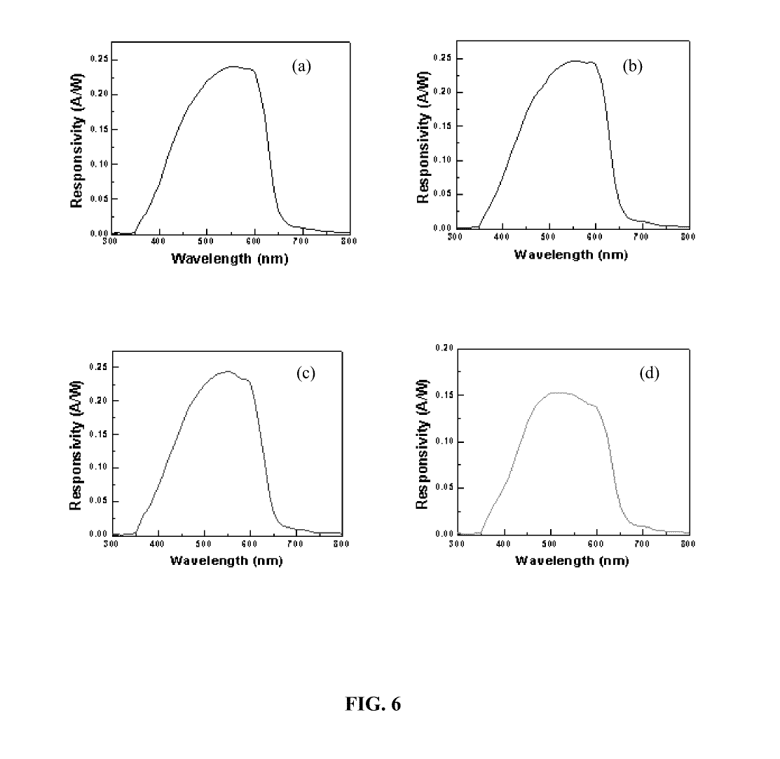

FIGS. 6a, 6b, 6c and 6d show the responsivity (Amps per Watt) of the prior art device, the first, second and third embodiments respectively. By comparing FIGS. 6a, 6b, 6c and 6d it can be seen that the presence of the thin interlayer does not substantially affect the responsivity.

It is found that the invention provides a physically robust arrangement. In order to investigate the adhesion of P3HT on PEDOT:PSS, extra optical spectroscopy measurements are carried out. Thin films of P3HT and PEDOT:PSS are prepared and treated exactly the same as in Example 1 or 2 except that the samples are based on Spectrosil B substrates instead of ITO substrates (see Example 3 set-out below). The absorption and photoluminescent (PL) spectra are taken before and after P3HT film being annealed, and measured again after being washed in chlorobenzene solvent. The absorption spectra are measured by Jasco V-560 UV/Vis Spectrophotometer, and PL spectra are measured by Jobin Yvon Horiba Fluoromax-3.

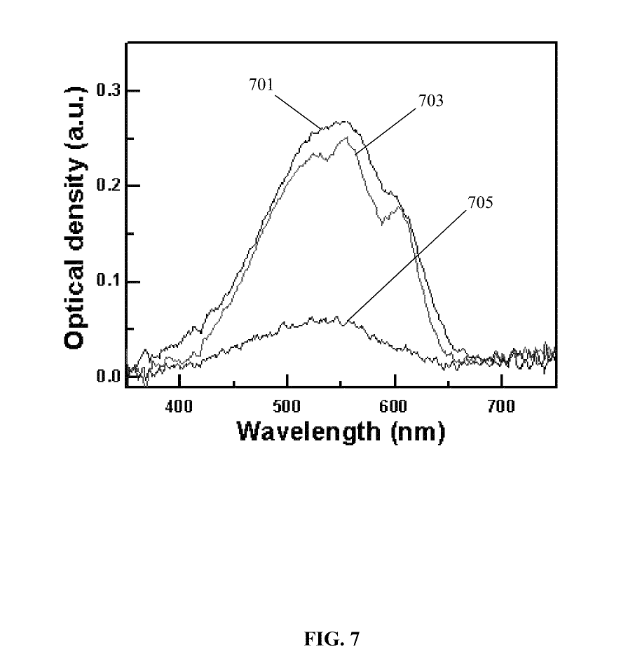

FIG. 7 illustrates the influence of thermal annealing treatment on absorption spectra of P3HT (10-20 nm) on PEDOT:PSS (50 nm) coated spectrosil B. Referring to FIG. 7: plot 701 shows the before annealing absorption spectra; plot 803 shows the absorption spectrum after annealing; and plot 705 shows the absorption spectrum after washing.

Before the annealing process, the absorption peak of the sample lies at 553 nm with a weak shoulder at 602 nm. After annealing, the intensity of the absorption has decreases a little. However, the absorption peak and the shoulder position have not shifted but the shoulder is more pronounced. After the annealed sample has been washed in chlorobenzene for 21 minutes, the intensity is only one fifth of that before washing. The detection of a spectrum after washing shows that some P3HT is still adhered to the PEDOT:PSS.

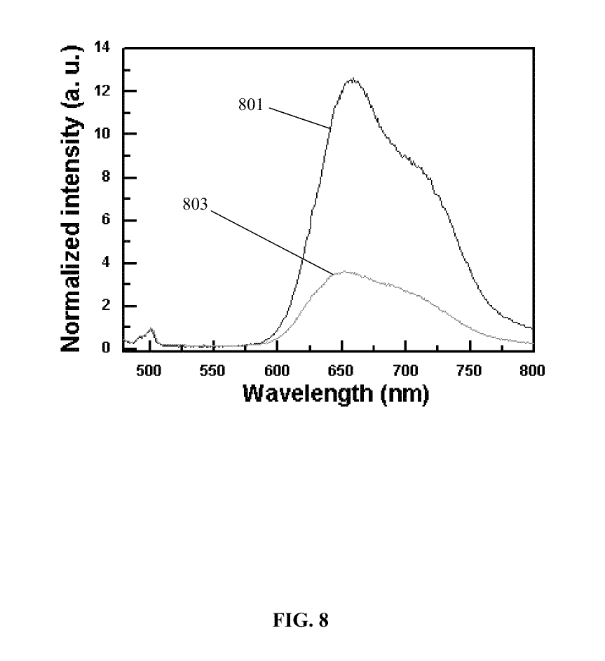

FIG. 8 illustrates the influence of thermal annealing on the photoluminescent (PL) spectra of P3HT (10-20 nm) on PEDOT:PSS (50 nm) coated on spectrosil B substrate. The photoluminescence before annealing (plot 801) has a peak at 657 nm and a shoulder at 712 nm. After annealing (plot 803), the spectrum has a peak at 649 nm with a shoulder at 705 nm. After being washed in chlorobenzene for 21 minutes, the sample shows no emission, although there is still a very small peak around the P3HT emission wavelength range (not shown in the FIG. 8).

FIGS. 7 and 8 show that both the absorption and the PL spectra are similar in shape before and after annealing but are of lower intensity. The possible reasons could be: 1) P3HT may be partially degraded due to high temperature annealing; or 2) Physically and/or chemically bonding to PEDOT:PSS surface, which affects the optical properties of P3HT. After washing in chlorobenzene for 21 minutes, the samples still have a noticeable signal. This suggests that the bonding between P3HT and PEDOT:PSS is very strong. This is similar to a permanent stable bond after thermal annealing. This has been found for TFB and BFE, e.g. TFB and BFE can form permanent bonding to PEDOT:PSS surface due to thermal annealing.

As the skilled reader will understand, the interlayer could comprise any other conjugated families, compounds, their derivatives, moieties etc, for example: polyfluorene, polyphenylenevinylene, poly(methyl methacrylate), polyvinylcarbazol (PVK) thiophene and their derivatives which include cross-linkable forms. Preferably, the polymer can form an amorphous phase and a permanent bond with the active layer. The polymer may be doped although it may be difficult to achieve uniform doping with a film thickness in accordance with the present invention.

The suitability of a particular conjugated polymer as the interlayer depends on many properties of the material such as: the energy levels relative to those of the active layer(s); the conductivity; the optical absorption; the chemical interaction with other layers; the material fluorescence; and optical interaction with the other layers. The choice of material may depend on the specific application of the photovoltaic device.

The interlayer according to any of the embodiments may be arranged between either or both electrodes and the active layer. Embodiments of the present invention provide an undoped interlayer. In being formed of only the pure material, the lifetime of the device is improved and, advantageously, less steps are involved in the fabrication process

Charge carriers will travel through the interlayer as they do in the active layer. Therefore, the skilled reader will understand the precise thickness of the interlayer is not critical. Any interlayer being more than just a monolayer but less than 30 nm is suitable. However, the skilled person will understand the thickness will affect the device performance.

The active layer in accordance with embodiments of the present invention may comprise any electron accepting material, such as a fullerene, and any electron donating material, such as a conjugated polymer, for example polythiophene.

As the skilled person will understand, any transparent electrode is suitable such as one formed from a layer of transparent conductive oxide, such as indium tin oxide, and a layer of a conductive organic material, such as PEDOT:PSS. Furthermore, the skilled person will understand the second electrode may be formed from any metal, such as aluminium or silver, or a combination of two or more metals, such as calcium and aluminium or calcium and silver or lithium fluoride and aluminium or lithium fluoride and silver.

The substrate may be any suitable material such as glass, for example borosilicate glass or sodalime glass, or plastic.

Embodiments of the present invention provide an improved low light level polymer-based detector with reduced dark current. Experiments show that the dark current is reduced from mA/cm² to nA/cm² by using the improved construction defined herein. However, the conductivity of the device may be reduced by the interlayer. The device may also be used as a solar cell owing to the suitable band gap provided by the interlayer.

### EXEMPLIFICATION

The invention will now be illustrated by reference to one or more of the following non-limiting examples:

### Example 1

### Device Made with P3HT Interlayer

All the devices according to embodiments of the present invention are fabricated on the pre-patterned indium-tin-oxide (ITO) glass substrates. The fabrication processes of the control device are described as following. The substrates are firstly carefully cleaned in ultrasonic bath of acetone and isopropanol for 15-20 minutes twice each in this sequence. Then, they are cleaned in isopropanol vapour, and dried properly on hotplate at a temperature above 100° C. This is followed by oxygen plasma treatment (for the embodiment here, the condition is at 100 W for 2.5 minutes). 50 nm thick Baytron P grade poly(styrenesulphonate)-doped poly(3,4-ethylenedioxythiophene) (PEDOT:PSS) is spin coated on the plasma treated ITO glass substrates and annealed in air at 140° C. for 30 minutes. For the fabrication of the P3HT interlayer, a 10-20 nm thick P3HT film from chlorobenzene solution is deposited by means of spin-coating and the samples are annealed in nitrogen (or glovebox filled with nitrogen) at 200° C. for 15-60 minutes. The active layer is 165 nm thick regioregular poly(3-hexylthiophene): 1-(3-Methoxycarbonylpropyl)-1-phenyl-[6.6]C61 (P3HT:PCBM) (1:1 wt. % in chlorobenzene) spin-coated in air and annealed at 50° C. for 2 hours in nitrogen (or glovebox filled with nitrogen). Then, top contact, 100 nm-thick aluminium electrode is thermally deposited at a pressure of at least 8×10⁻⁶ mbar through a shadow mask, defining the active device area of 0.045 mm². Finally, the post annealing process of the devices is carried out on the hotplate in nitrogen (or glovebox filled with nitrogen) at 140° C. for 1 hour.

The first example provides a number of advantages in the fabrication process and resulting assembly. Firstly, the interlayer is insoluble after it is formed on the PEDOT:PSS. Thus, it is not damaged during the (solution) process whereby the active layer is deposited. This helps keep the interlayer intact and ensure it functions as required. Secondly, the method in accordance with the first example is very straightforward. Thirdly, the method is less likely to introduce contaminates than prior art methods using doping and treatment at a later stage of the process.

### Example 2

### Device Made with Other Interlayers

For comparison, two other materials have also been investigated as alternative interlayer material at the same time. They are the derivatives of polyfluorenes: poly[2,7-(9,9-di-n-octylfluorene)-alt-(1,4-phenylene-((4-secbutylphenyl)imino)-1,4-phenylene)](TFB) and poly[9,9-diocytlfluorene-co-(bis-N,N′-(3-ethoxyphenyl)-bis-N,N′-phenylbenzidine)](BFE). The fabrication processes are: after PEDOT:PSS deposited as described above in Example 1, a 15 nm thick TFB or BFE film is deposited from their xylene solutions and annealed in nitrogen (or glovebox filled with nitrogen) at 180° C. for 15 minutes. The other steps are the same as described in Example 1

### Example 3

### Device Made on Alternative Substrate

A device may also be made by following the steps set-out in Example 1 or 2 but using a Spectrosil B substrate instead of indium tin oxide.

1. A photovoltaic device comprising:
a substrate;
a first electrode;
a second electrode;
an active layer arranged between the first and second electrodes; and
an interlayer comprising an undoped conjugated polymer arranged between the active layer and at least one of the electrodes.

2. A photovoltaic device as claimed in claim 1 wherein the polymer is amorphous.

3. A photovoltaic device as claimed in claim 1 wherein the polymer comprises a material select from the group comprising P3HT, TFB and BFE.

4. A photovoltaic device as claimed in claim 1 comprising a first interlayer arranged between the first electrode and the active layer and a second interlayer between the active layer and second electrode.

5. A photovoltaic device as claimed in claim 4 in which at least one of the interlayers is amorphous.

6. A photovoltaic device as claimed in claim 4 in which the first interlayer is an undoped conjugated polymer selected from the group comprising P3HT, TFB and BFE.

7. A photovoltaic device as claimed in claim 4 in which the second interlayer is an undoped conjugated polymer selected from the group comprising P3HT, TFB and BFE.

8. A device as claimed in claim 4 in which the thickness of the interlayer(s) is no more than 30 nm, preferably in which the thickness of the interlayer(s) is in the range approximately 10 to 20 nm.

9. A device as claimed in claim 4 wherein the active layer comprises a mixture of two or more active materials.

10. A device as claimed in claim 4 wherein the active layer comprises a mixture of an electron accepting material and an electron donating material.

11. A device as claimed in claim 10 where in the electron accepting material comprises a fullerene.

12. A device as claimed in claim 10 wherein the electron donating material comprises a conjugated polymer.

13. A device as claimed in claim 12 wherein the conjugated polymer comprising the electron donating material comprises polythiophene.

14. A device as claimed in claim 9 in which the active layer comprises a mixture of P3HT and PCBM.

15. A device as claimed in claim 14 in which the ratio of P3HT to PCBM in the active layer is 1:1.

16. A device as claimed in claim 14 in which the first electrode is transparent and formed from a layer of a transparent conductive oxide and a layer of a transparent conductive organic material.

17. A device as claimed in claim 16 in which the transparent conductive oxide comprises indium tin oxide

18. A device as claimed in claim 16 wherein the conductive organic material comprises PEDOT:PSS.

19. A device as claimed in claim 16 in which the second electrode is formed from at least one metal.

20. A device as claimed in claim 19 in which the at least one metal comprises aluminium or silver.
